(19) United States
(12) Patent Application Publication
(10) Pub. No.: US 2026/0312688 A1
(43) Pub. Date: Oct. 8, 2026

(54) OPTICAL TRANSCEIVER MODULE, OPTICAL COMMUNICATION SYSTEM, AND METHOD OF SIGNAL AMPLIFICATION

(71) Applicant: SUMITOMO ELECTRIC INDUSTRIES, LTD., Osaka-shi, Osaka (JP)

(72) Inventors: Naruto TANAKA, Osaka-shi (JP); Daisuke KAWASE, Osaka-shi (JP)

(73) Assignee: SUMITOMO ELECTRIC INDUSTRIES, LTD., Osaka-shi, Osaka (JP)

(21) Appl. No.: 19/476,947

(22) PCT Filed: Feb. 22, 2024
(86) PCT No.: PCT/JP2024/006417

§ 371 Date: Oct. 20, 2025

(30) Foreign Application Priority Data
May 18, 2023 (JP) 2023-081943

(51) Int. Cl. H04B 10/40

(52) U.S. Cl. CPC H04B 10/40

(57) ABSTRACT

An optical transmission/reception module includes: a light reception element that converts an analog optical signal into a current signal; a resistor that converts the current signal into a voltage signal; a fully differential amplifier that amplifies the voltage signal; a first inductor having a first end connected to a first power supply node and a second end connected to a cathode of the light reception element; a second inductor having a first end connected to a second power supply node and a second end connected to an anode of the light reception element; a first capacitor connected between a first node between the cathode and the first inductor and a first end of the resistor; and a second capacitor connected between a second node between the anode and the second inductor and a second end of the resistor

### TECHNICAL FIELD

The present disclosure relates to an optical transceiver module, an optical communication system, and a method of signal amplification.

This application claims priority based on Japanese Patent Application No. 2023-81943, filed May 18, 2023, the disclosure of which is all incorporated herein by reference.

### BACKGROUND ART

PTL 1 (Japanese Unexamined Patent Application Publication (Translation of PCT Application) No. 2008-510383) discloses a signal power level detection circuit as follows. The signal power level detection circuit includes a photodetector having an anode and a cathode, an amplifier having at least two input terminals and two output terminals, and a signal detector connected to one of the output terminals of the amplifier. One of the input terminals of the amplifier is connected to the anode of the photodetector, the other of the input terminals of the amplifier is connected to the cathode of the photodetector, and the two output terminals of the amplifier are isolated from each other.

### CITATION LIST

### Patent Literature

PTL 1: Japanese Unexamined Patent Application Publication (Translation of PCT Application) No. 2008-510383

### SUMMARY OF INVENTION

An optical transceiver module according to the present disclosure is configured to transmit and receive an optical signal, is provided inside a housing having a shielding effect, and is able to simultaneously transmit and receive an analog optical signal corresponding to a radio signal. The optical transceiver module includes a photodetector configured to convert a received analog optical signal into a current signal; a resistor for converting into a voltage signal the current signal obtained through conversion by the photodetector; a fully differential amplifier configured to amplify the voltage signal obtained through conversion by the resistor; a first inductor having a first end and a second end, the first end being connected to a first power supply node, the second end being connected to a cathode of the photodetector; a second inductor having a first end and a second end, the first end being connected to a second power supply node, the second end being connected to an anode of the photodetector; a first capacitor connected between a first node and a first end of the resistor, the first node being located between the cathode and the first inductor; and a second capacitor connected between a second node and a second end of the resistor, the second node being located between the anode and the second inductor.

One aspect of the present disclosure can be achieved not only as an optical transceiver module but also as a semiconductor integrated circuit that achieves part or all of the optical transceiver module, or as an optical communication system including the optical transceiver module.

### BRIEF DESCRIPTION OF DRAWINGS

FIG. 1 is a diagram illustrating a configuration of an optical communication system according to an embodiment of the present disclosure.

FIG. 2 is a diagram illustrating a circuit configuration of an optical transceiver module according to the embodiment of the present disclosure.

FIG. 3 is a diagram illustrating a portion of a configuration of the optical transceiver module according to the embodiment of the present disclosure.

FIG. 4 is a graph illustrating isolation performance of the optical transceiver module according to the embodiment of the present disclosure.

FIG. 5 is a flowchart defining an example of an operation procedure for performing a method of signal amplification using the optical transceiver module according to the embodiment of the present disclosure.

FIG. 6 is a diagram illustrating a circuit configuration of an optical transceiver module according to a modification of the embodiment of the present disclosure.

FIG. 7 is a graph illustrating isolation performance of the optical transceiver module according to the modification of the embodiment of the present disclosure.

### DETAILED DESCRIPTION

Techniques have been developed for receiving an optical signal and amplifying an electrical signal based on the received optical signal.

### Problems to be Solved by Present Disclosure

Improving isolation between a transmitted signal and a received signal is desirable for an optical transceiver module configured to transmit and receive optical signals.

The present disclosure has been made to solve the above-mentioned problem, and its purpose is to provide an optical transceiver module, an optical communication system, and a method of signal amplification that are capable of improving isolation between a transmitted signal and a received signal.

### Advantageous Effects of Present Disclosure

According to the present disclosure, isolation between a transmitted signal and a received signal can be improved for an optical transceiver module configured to transmit and receive optical signals.

### Description of Embodiments of Present Disclosure

First, details of the embodiments of the present disclosure will be listed and described.

(1) An optical transceiver module according to an embodiment of the present disclosure is configured to transmit and receive an optical signal, is provided inside a housing having a shielding effect, and is able to simultaneously transmit and receive an analog optical signal corresponding to a radio signal. The optical transceiver module includes a photodetector configured to convert a received analog optical signal into a current signal; a resistor for converting into a voltage signal the current signal obtained through conversion by the photodetector; a fully differential amplifier configured to amplify the voltage signal obtained through conversion by the resistor; a first inductor having a first end and a second end, the first end being connected to a first power supply node, the second end being connected to a cathode of the photodetector; a second inductor having a first end and a second end, the first end being connected to a second power supply node, the second end being connected to an anode of the photodetector; a first capacitor connected between a first node and a first end of the resistor, the first node being located between the cathode and the first inductor; and a second capacitor connected between a second node and a second end of the resistor, the second node being located between the anode and the second inductor.

In this manner, a current signal based on a received optical signal is converted into a voltage signal using a resistor, and the voltage signal can be amplified using an amplifier having a wide dynamic range. Furthermore, a configuration in which a fully differential amplifier is used as an amplifier for amplifying a voltage signal enables common-mode noise to be cancelled in a portion susceptible to influence of a transmitted signal, such as a transmission path from a photodetector to a first-stage amplifier and the first-stage amplifier, in a transmission path from the photodetector to the output terminal of the optical transceiver module. Thus, isolation between a transmitted signal and a received signal can be improved for an optical transceiver module configured to transmit and receive optical signals.

(2) In (1) above, a capacitance value of the first capacitor and a capacitance value of the second capacitor may be set to values for which a frequency component included in the current signal is allowed to pass, the frequency component having a frequency of a predetermined value or higher, and an inductance value of the first inductor and an inductance value of the second inductor may be set to values for which the frequency component is blocked.

In this configuration, isolation between a transmitted signal and a received signal can be improved, for example, in an optical communication system where light is modulated with an electrical signal obtained by superimposition of a high-frequency communication signal and a low-frequency control signal and where the modulated light is transmitted.

(3) In (1) or (2) above, the optical transceiver module may further include a transmission line connecting an optical receiver including the photodetector and a circuit board on which the first capacitor and the second capacitor are mounted; and a termination circuit having a first end and a second end, the first end being connected to a third node between the cathode and the transmission line, the second end being connected to a fourth node between the anode and the transmission line, the termination circuit being configured to eliminate a mismatch between a characteristic impedance of the optical receiver and a characteristic impedance of the resistor and the transmission line.

In this configuration, the first capacitor and the second capacitor can be mounted on a circuit board external to the optical receiver, thereby reducing the size of the optical receiver. In addition, reflection of a signal at an end portion of the optical receiver can be reduced.

(4) In (3) above, the termination circuit may include a first resistor, a capacitor, and a second resistor connected in series in this order.

In this configuration, reflection of a signal at an end portion of the optical receiver can be reduced while a current signal can be output from the photodetector to the circuit board via the transmission line.

(5) An optical communication system according to the embodiment of the present disclosure includes a master station apparatus including the optical transceiver module according to (1) above and a signal processing unit; and a slave station apparatus including the optical transceiver module according to (1) above and a radio frequency transceiver unit. The master station apparatus is configured to receive an analog signal from a base station apparatus and transmit to the slave station apparatus via an optical fiber the analog optical signal of a first type corresponding to the radio signal of a first type based on the analog signal, the slave station apparatus is configured to transmit to an antenna the radio signal of the first type corresponding to the analog optical signal of the first type, the slave station apparatus is configured to receive the radio signal of a second type from the antenna and transmit to the master station apparatus via the optical fiber the analog optical signal of a second type corresponding to the radio signal of the second type, and the master station apparatus is configured to transmit to the base station apparatus a signal based on the radio signal of the second type corresponding to the analog optical signal of the second type.

In this configuration, isolation between radio signals in the master station apparatus and the slave station apparatus can be improved, thereby improving the communication quality in the optical communication system.

(6) A method of signal amplification according to the embodiment of the present disclosure is a method of signal amplification for an optical transceiver module configured to transmit an optical signal corresponding to an analog electrical signal being input and output an analog electrical signal corresponding to an optical signal being received. The method includes converting using a photodetector an optical signal being received into a current signal; converting using a resistor into a voltage signal the current signal obtained through conversion; and amplifying using a fully differential amplifier the voltage signal obtained through conversion.

In this manner, a current signal based on a received optical signal is converted into a voltage signal using a resistor, and the voltage signal can be amplified using an amplifier having a wide dynamic range. Furthermore, a method employing a fully differential amplifier as an amplifier for amplifying a voltage signal enables common-mode noise to be cancelled in a portion susceptible to influence of a transmitted signal, such as a transmission path from a photodetector to a first-stage amplifier and the first-stage amplifier, in a transmission path from the photodetector to the output terminal of the optical transceiver module. Thus, isolation between a transmitted signal and a received signal can be improved for an optical transceiver module configured to transmit and receive optical signals.

Hereinafter, an embodiment of the present disclosure will be described with reference to the drawings. The same or corresponding parts in the figures are assigned the same symbols, and their descriptions will not be repeated. At least some portions of the embodiment described below may be combined in any manner.

### Configuration and Basic Operation

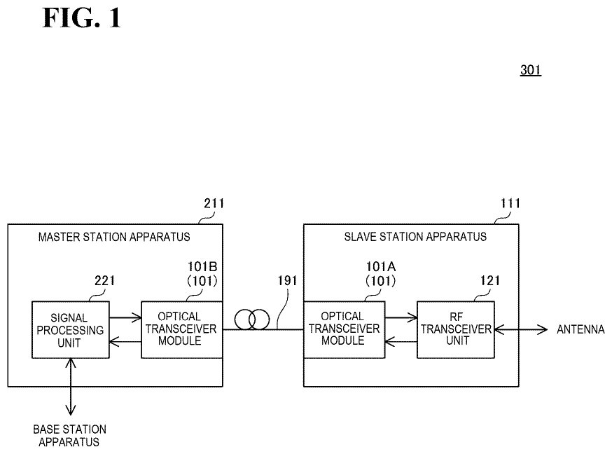

FIG. 1 is a diagram illustrating a configuration of an optical communication system according to the embodiment of the present disclosure. With reference to FIG. 1, an optical communication system 301 includes a slave station apparatus 111 and a master station apparatus 211. The slave station apparatus 111 and the master station apparatus 211 are connected to each other via an optical fiber 191. The optical communication system 301 may include a plurality of slave station apparatuses 111. In such a case, for example, a plurality of slave station apparatuses 111 are connected to the master station apparatus 211 via a single optical fiber 191 and an optical coupler. For example, the optical communication system 301 is an analog Radio over Fiber (RoF) system. The slave station apparatus 111 and the master station apparatus 211 transmit and receive analog optical signals corresponding to radio signals, that is, radio frequency (RF) signals. Hereinafter, an analog optical signal is simply referred to as an optical signal in some cases.

The slave station apparatus 111 includes an optical transceiver module 101A and an RF transceiver unit 121. The master station apparatus 211 includes an optical transceiver module 101B and a signal processing unit 221. Hereinafter, each of the optical transceiver modules 101A and 101B will also be referred to as an optical transceiver module 101. The optical transceiver module 101 transmits an optical signal corresponding to an analog electrical signal being input and outputs an analog electrical signal corresponding to an optical signal being received. For example, the optical transceiver module 101 is housed in a single metal housing.

The optical transceiver modules 101A and 101B are connected to each other via the optical fiber 191. For example, the optical transceiver module 101 is a small pluggable type module, such as a small form-factor pluggable (SFP). Examples of the optical transceiver module 101 are not limited to an SFP and may include a quad small form-factor pluggable (QSFP) and a 10 Gigabit small form factor pluggable (XFP). However, an SFP is smaller than a QSFP and an XFP and thus more preferable for the optical transceiver module 101.

The slave station apparatus 111 and the master station apparatus 211 transmit and receive optical signals containing communication data via the optical fiber 191. Hereinafter, an optical signal transmitted from the slave station apparatus 111 to the master station apparatus 211 is also referred to as an uplink optical signal, and an optical signal transmitted from the master station apparatus 211 to the slave station apparatus 111 is also referred to as a downlink optical signal. The slave station apparatus 111 and the master station apparatus 211 may be connected to each other via two optical fibers 191. In such a case, the slave station apparatus 111 and the master station apparatus 211 transmit and receive uplink optical signals via a first optical fiber 191 and transmit and receive downlink optical signals via a second optical fiber 191.

When the optical communication system 301 is applied to mobile wireless communication, for example, a time division duplex (TDD) system is adopted in the mobile wireless communication. In such a case, the optical communication system 301 switches between an uplink transmission period for transmitting communication data from the slave station apparatus 111 to the master station apparatus 211 and a downlink transmission period for transmitting communication data from the master station apparatus 211 to the slave station apparatus 111, and these periods are repeated alternately.

### Downlink Communication

The signal processing unit 221 in the master station apparatus 211 receives from a base station apparatus (not illustrated) an analog signal modulated by orthogonal frequency division multiplexing (OFDM) and including communication data. The signal processing unit 221 performs frequency conversion on the received analog signal to generate an RF signal Srd, which is an analog electrical signal. The RF signal Srd is an example of a radio signal of a first type. The signal processing unit 221 outputs the generated RF signal Srd to the optical transceiver module 101B during a downlink transmission period. For example, during a downlink transmission period, the signal processing unit 221 outputs to the optical transceiver module 101B an electrical signal in which a digital control signal CS1 for controlling the slave station apparatus 111 and the RF signal Srd are superimposed. The signal processing unit 221 may be configured to receive the RF signal Srd from the base station apparatus and output the received RF signal Srd to the optical transceiver module 101b.

The optical transceiver module 101B converts the electrical signal received from the signal processing unit 221 into an optical signal. In more detail, the optical transceiver module 101B receives the electrical signal containing the RF signal Srd from the signal processing unit 221 and generates a downlink optical signal with a wavelength 21 modulated with the received electrical signal. A downlink optical signal is an example of an analog optical signal of a first type. The optical transceiver module 101B transmits the generated downlink optical signal to the optical fiber 191.

The optical transceiver module 101A in the slave station apparatus 111 converts the optical signal received via the optical fiber 191 into an electrical signal. In more detail, the optical transceiver module 101A receives the downlink optical signal from the master station apparatus 211 via the optical fiber 191. The optical transceiver module 101A generates an electrical signal at a level in accordance with the intensity of the received downlink optical signal. The optical transceiver module 101A amplifies the generated electrical signal and outputs the amplified electrical signal to the RF transceiver unit 121.

The RF transceiver unit 121 receives the electrical signal from the optical transceiver module 101A and separates the received electrical signal into the control signal CS1 and the RF signal Srd. The RF transceiver unit 121 operates in accordance with the control signal CS1 obtained by separation. The RF transceiver unit 121 transmits the RF signal Srd obtained by separation to a mobile communication terminal via an antenna (not illustrated). The RF transceiver unit 121 may be configured to transmit a signal based on the RF signal Srd to another apparatus via a wire line.

The RF signal Srd transmitted to the mobile communication terminal from the RF transceiver unit 121 via the antenna does not necessarily coincide completely with the RF signal Srd generated by the signal processing unit 221. During the transmission from the master station apparatus 211 to the slave station apparatus 111, the RF signal Srd may be subjected to a carrier frequency shift that does not affect the content of the communication between the base station apparatus and the mobile communication terminal and may be subjected to modifications such as superimposition and suppression of another signal that is not related to the content of the communication.

### Uplink Communication

The RF transceiver unit 121 in the slave station apparatus 111 receives from a mobile communication terminal via an antenna (not illustrated) an RF signal Sru, which is an analog electrical signal modulated by OFDM in a millimeter-wave band containing communication data. The RF signal Sru is an example of a radio signal of a second type. The RF transceiver unit 121 outputs the received RF signal Sru to the optical transceiver module 101A during an uplink transmission period. Instead of receiving the RF signal Sru via an antenna, the RF transceiver unit 121 may be configured to receive a signal containing communication data via a wire line and generate the RF signal Sru based on the received signal. For example, the frequency band of the RF signal Sru and the frequency band of the RF signal Srd at least partially overlap each other.

The optical transceiver module 101A converts the electrical signal received from the RF transceiver unit 121 into an optical signal. In more detail, the optical transceiver module 101A receives the electrical signal containing the RF signal Sru from the RF transceiver unit 121 and generates an uplink optical signal with a wavelength 22 modulated with the received electrical signal. An uplink optical signal is an example of an analog optical signal of a second type. The optical transceiver module 101A transmits the generated uplink optical signal to the optical fiber 191.

The optical transceiver module 101B in the master station apparatus 211 converts the optical signal received via the optical fiber 191 into an electrical signal. In more detail, the optical transceiver module 101B receives the uplink optical signal from the slave station apparatus 111 via the optical fiber 191. The optical transceiver module 101B generates an RF signal Sru, which is an electrical signal at a level in accordance with the intensity of the received uplink optical signal. The optical transceiver module 101B amplifies the generated RF signal Sru and outputs the amplified RF signal Sru to the signal processing unit 221.

The signal processing unit 221 receives the RF signal Sru from the optical transceiver module 101B and transmits to the base station apparatus an analog signal obtained by frequency conversion, such as down conversion, of the received RF signal Sru. The signal processing unit 221 may be configured to transmit the RF signal Sru received from the optical transceiver module 101B to the base station apparatus without frequency conversion. The signal processing unit 221 may be configured to adjust the level of the RF signal Sru received from the optical transceiver module 101B and transmit to the base station apparatus a level-adjusted RF signal Sru or a signal obtained by frequency conversion of the level-adjusted RF signal Sru.

The RF signal Sru received by the signal processing unit 221 from the optical transceiver module 101B does not necessarily coincide completely with the RF signal Sru received by the RF transceiver unit 121 from the mobile communication terminal via the antenna. During the transmission from the slave station apparatus 111 to the master station apparatus 211, the RF signal Sru may be subjected to a carrier frequency shift that does not affect the content of the communication between the base station apparatus and the mobile communication terminal and may be subjected to modifications such as superimposition and suppression of another signal that is not related to the content of the communication.

### Problem

As described above, the optical transceiver module 101 transmits and receives optical signals. For example, the optical transceiver module 101 may simultaneously transmit and receive optical signals corresponding to RF signals. In more detail, although an uplink transmission period and a downlink transmission period alternately appear in accordance with the above-mentioned TDD system, there may be a time that the period in which the optical transceiver module 101 processes the RF signal Srd partially overlaps the period in which the optical transceiver module 101 processes the RF signal Sru.

In such a case, for example, noise caused by the RF signal Sru may be superimposed on the RF signal Srd in the optical transceiver module 101A in the slave station apparatus 111. Furthermore, for example, noise caused by the RF signal Srd may be superimposed on the RF signal Sru in the optical transceiver module 101B in the master station apparatus 211.

Thus, the optical transceiver module 101 according to the embodiment of the present disclosure solves the above problem by adopting the following configuration.

### Optical Transceiver Module

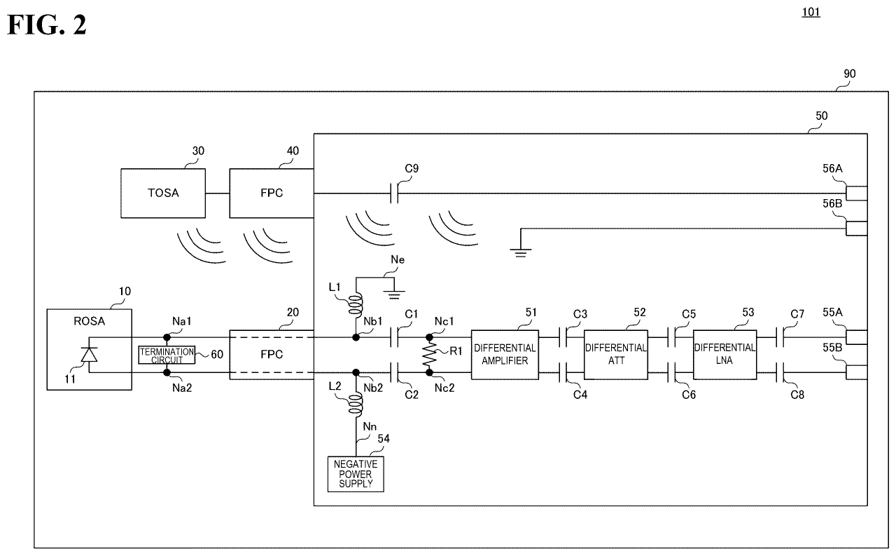

FIG. 2 is a diagram illustrating a circuit configuration of an optical transceiver module according to the embodiment of the present disclosure. With reference to FIG. 2, the optical transceiver module 101 includes a receiver optical subassembly (ROSA) 10, a transmitter optical subassembly (TOSA) 30, flexible printed circuits (FPCs) 20 and 40, a circuit board 50, and a termination circuit 60. The ROSA 10 is an example of an optical receiver. The FPCs 20 and 40 are each an example of a transmission line.

The optical transceiver module 101 is provided inside a housing 90 having a shielding effect. The housing 90 is made of metal and has an electromagnetic shielding effect to shield the inside from the outside. The housing 90 is not configured to partially shield internal portions of the housing 90. That is, the housing 90 neither provides shielding between the transmission path for the RF signal Srd and the transmission path for the RF signal Sru nor shields a plurality of spaces inside the housing 90 from each other.

The FPC 20 connects the ROSA 10 and the circuit board 50. The FPC 40 connects the TOSA 30 and the circuit board 50.

The ROSA 10 is connected to the optical fiber 191. The ROSA 10 includes a photo diode (PD) 11, which is a photodetector. The ROSA 10 is connected to the circuit board 50 via the FPC 20. In more detail, the cathode and the anode of the PD 11 are connected to the circuit board 50 via the FPC 20. The PD 11 converts a received optical signal into a current signal. In more detail, the PD 11 receives an optical signal corresponding to an RF signal via the optical fiber 191, converts the received optical signal into a current signal, and outputs the current signal to the circuit board 50 via the FPC 20.

The TOSA 30 is connected to the optical fiber 191. The TOSA 30 includes a laser diodo (LD) (not illustrated). The TOSA 30 is connected to the circuit board 50 via the FPC 40. The LD receives an RF signal from the circuit board 50 via the FPC 40, converts the received RF signal into an optical signal, and outputs the optical signal to the optical fiber 191.

The circuit board 50 includes a differential amplifier 51, a differential attenuator (ATT) 52, a differential low noise amplifier (LNA) 53, a negative power supply 54, output connectors 55A and 55B, input connectors 56A and 56B, a resistor R1, inductors L1 and L2, and capacitors C1, C2, C3, C4, C5, C6, C7, C8, and C9. That is, the circuit board 50 is a board on which the differential amplifier 51, the differential ATT 52, the differential LNA 53, the negative power supply 54, the output connectors 55A and 55B, the input connectors 56A and 56B, the resistor R1, the inductors L1 and L2, and the capacitors C1, C2, C3, C4, C5, C6, C7, C8, and C9 are mounted. The resistor R1 may be built into the differential amplifier 51. The differential amplifier 51 is an example of a fully differential amplifier. The inductor L1 is an example of a first inductor. The inductor L2 is an example of a second inductor. The capacitor C1 is an example of a first capacitor. The capacitor C2 is an example of a second capacitor. The differential amplifier 51 and the differential LNA 52 are each a fully differentially driven amplifier. The differential ATT 52 is a fully differentially driven attenuator.

The input connectors 56A and 56B are terminals to which RF signals are input from outside the optical transceiver module 101. The input connectors 56A and 56B, the capacitor C9, the FPC 40, and the TOSA 30 form a transmission path for converting an RF signal received from outside the optical transceiver module 101 into an optical signal and outputting the optical signal to the optical fiber 191.

The output connectors 55A and 55B are terminals for outputting an RF signal to outside the optical transceiver module 101. The ROSA 10, the FPC 20, the differential amplifier 51, the differential ATT 52, the differential LNA 53, the inductors L1 and L2, the capacitors C1, C2, C3, C4, C5, C6, C7, and C8, and the input connectors 56A and 56B form a transmission path for converting an optical signal received via the optical fiber 191 into an RF signal and outputting the RF signal.

That is, a first transmission path, which is a transmission path for an RF signal to be converted into an optical signal to be output, and a second transmission path, which is a transmission path for an RF signal converted from a received optical signal, are provided inside the single housing 90. The housing 90 does not provide shielding between the first transmission path and the second transmission path.

The inductor L1 has a first end connected to a ground node Ne and a second end connected to the cathode of the PD 11 via the FPC 20. The ground node Ne is an example of a first power supply node.

The inductor L2 has a first end connected to a connection node Nn to which the negative power supply 54 is connected and a second end connected to the anode of the PD 11 via the FPC 20. The connection node Nn is an example of a second power supply node. The negative power supply 54 supplies a negative voltage lower than the GND level.

The capacitor C1 is connected between a node Nb1 located between the cathode of the PD 11 and the inductor L1 and a first end of the resistor R1. That is, the capacitor C1 has a first end connected to the cathode of the PD 11 via the FPC 20, and a second end connected to the resistor R1. The node Nb1 is an example of a first node.

The capacitor C2 is connected between a node Nb2 located between the anode of the PD 11 and the inductor L2 and a second end of the resistor R1. That is, the capacitor C2 has a first end connected to the anode of the PD 11 via the FPC 20, and a second end connected to the resistor R1. The node Nb2 is an example of a second node.

The resistor R1 converts a current signal obtained through conversion by the PD 11 into a voltage signal. In more detail, the resistor R1 has the first end connected to the second end of the capacitor C1 and the second end connected to the second end of the capacitor C2.

The differential amplifier 51 has a first input terminal connected to a node Nc1 located between the capacitor C1 and the resistor R1, a second input terminal connected to a node Nc2 located between the capacitor C2 and the resistor R1, a first output terminal connected to a first end of the capacitor C3, and a second output terminal connected to a first end of the capacitor C4. The differential amplifier 51 amplifies the voltage signal obtained through conversion by the resistor R1. In more detail, the differential amplifier 51 receives the voltage signal via the two input terminals and amplifies the received voltage signal by a predetermined amplification factor. The differential amplifier 51 outputs the amplified voltage signal from the two output terminals.

The capacitor C3 has the first end connected to the first output terminal of the differential amplifier 51 and a second end connected to a first input terminal of the differential ATT 52. The capacitor C4 has the first end connected to the second output terminal of the differential amplifier 51 and a second end connected to a second input terminal of the differential ATT 52.

The differential ATT 52 has the first input terminal connected to the second end of the capacitor C3, the second input terminal connected to the second end of the capacitor C4, a first output terminal connected to a first end of the capacitor C5, and a second output terminal connected to a first end of the capacitor C6. The differential ATT 52 receives a voltage signal via the two input terminals and attenuates the received voltage signal by a predetermined attenuation factor. The differential ATT 52 outputs the attenuated voltage signal from the two output terminals.

The capacitor C5 has the first end connected to the first output terminal of the differential ATT 52 and a second end connected to a first input terminal of the differential LNA 53. The capacitor C6 has the first end connected to the second output terminal of the differential ATT 52 and a second end connected to a second input terminal of the differential LNA 53.

The differential LNA 53 has the first input terminal connected to the second end of the capacitor C5, the second input terminal connected to the second end of the capacitor C6, a first output terminal connected to a first end of the capacitor C7, and a second output terminal connected to a first end of the capacitor C8. The differential LNA 53 receives a voltage signal via the two input terminals and amplifies the received voltage signal by a predetermined amplification factor. The differential LNA 53 outputs the amplified voltage signal from the two output terminals.

The capacitor C7 has the first end connected to the first output terminal of the differential LNA 53 and a second end connected to the output connector 55A. The capacitor C8 has the first end connected to the second output terminal of the differential LNA 53 and a second end connected to the output connector 55B. The voltage signal output from the differential LNA 53 is output to outside the circuit board 50 via the capacitors C7 and C8 and the output connectors 55A and 55B.

The capacitor C9 has a first end connected to the input connector 56A and a second end connected to the TOSA 30 via the FPC 40. The input connector 56B is connected to a ground node.

For example, an inductance value IV1 of the inductor L1 and an inductance value IV2 of the inductor L2 are set to values for which frequency components of a predetermined frequency f1 or higher that are included in the current signal obtained through conversion by the PD 11 are blocked. In more detail, for example, the inductance values IV1 and IV2 are set to values for which the gain of the circuit formed by the inductors L1 and L2 is less than −3 dB for frequency components of the frequency f1 or higher. For example, the frequency f1 is the frequency of the control signal CS1.

For example, a capacitance value CV1 of the capacitor C1 and a capacitance value CV2 of the capacitor C2 are set to values for which frequency components of the frequency f1 or higher that are included in the current signal obtained through conversion by the PD 11 are allowed to pass. In more detail, for example, the capacitance values CV1 and CV2 are set to values for which the gain of the circuit formed by the capacitors C1 and C2 is −3 dB or more for frequency components of the frequency f1 or higher. By setting the inductance values IV1 and IV2 and the capacitance values CV1 and CV2 in this manner, the control signal CS1 containing low-frequency components can be transmitted satisfactorily.

The termination circuit 60 has a first end connected to a node Na1 located between the cathode of the PD 11 and the FPC 20 and a second end connected to a node Na2 located between the anode of the PD 11 and the FPC 20. The node Na1 is an example of a third node. The node Na2 is an example of a fourth node. The termination circuit 60 is a circuit for eliminating a mismatch between the characteristic impedance of the ROSA 10 and the characteristic impedance of the resistor R1 and the FPC 20.

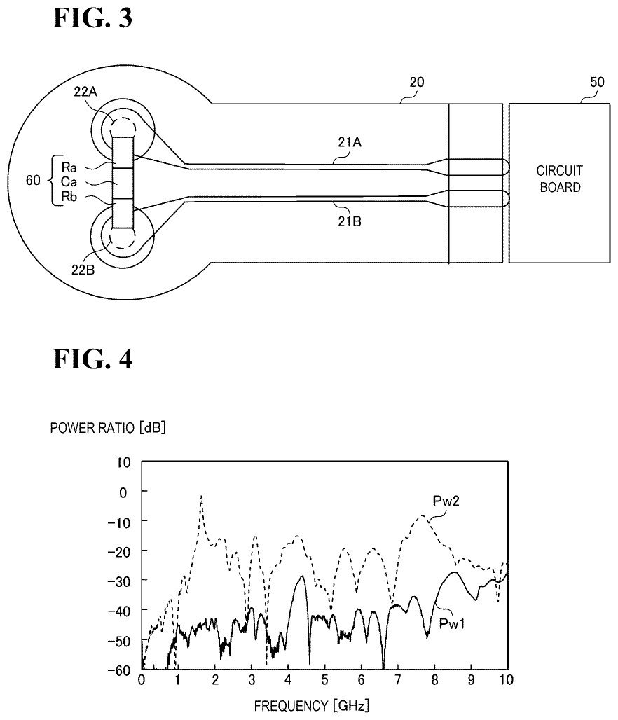

FIG. 3 is a diagram illustrating a portion of a configuration of the optical transceiver module according to the embodiment of the present disclosure. FIG. 3 illustrates a detailed configuration of the FPC 20 and the termination circuit 60.

With reference to FIG. 3, the FPC 20 includes transmission traces 21A and 21B. The transmission trace 21A is connected to the cathode of the PD 11 through a via 22A. The transmission trace 21B is connected to the anode of the PD 11 through a via 22B. The vias 22A and 22B correspond to an end portion of the ROSA 10.

The termination circuit 60 includes a resistor Ra, a capacitor Ca, and a resistor Rb connected in series in this order. In other words, the resistors Ra and Rb and the capacitor Ca are connected symmetrically along the arrangement direction of the resistors Ra and Rb and the capacitor Ca. The resistor Ra is an example of a first resistor. The resistor Rb is an example of a second resistor.

In more detail, the resistor Ra has a first end connected to the via 22A and a second end connected to the capacitor Ca. The capacitor Ca has a first end connected to the resistor Ra and a second end connected to the resistor Rb. The resistor Rb has a first end connected to the capacitor Ca and a second end connected to the via 22B.

The resistance values of the resistors Ra and Rb and the capacitance value of the capacitor Ca are set in accordance with the impedance of the FPC 20. For example, when the characteristic impedance of the FPC 20 is 50 Ω, the resistance value of the resistor Ra and the resistance value of the resistor Rb are set to 50 Ω or 51 Ω. For example, the capacitance value of the capacitor Ca is set to 0.1 μf.

FIG. 4 is a graph illustrating isolation performance of the optical transceiver module according to the embodiment of the present disclosure. In FIG. 4, the horizontal axis represents the frequency [GHz] of the input/output signals, and the vertical axis represents the power ratio [dB]. The solid line in FIG. 4 indicates a power ratio Pw1, which is a power ratio Pw obtained by dividing the power of the signal output from the output connectors 55A and 55B by the power of the signal that is input to the input connectors 56A and 56B from outside the optical transceiver module 101 while the optical transceiver module 101, which is an SFP, is not receiving an optical signal. The dashed line in FIG. 4 indicates a power ratio Pw2, which is the power ratio Pw for an optical transceiver module including a single-ended amplifier and a single-ended attenuator instead of the differential amplifier 51, the differential ATT 52, and the differential LNA 53, as compared with the optical transceiver module 101.

With reference to FIG. 4, for the optical transceiver module 101, which is an SFP, the power ratio Pw can be reduced to approximately −30 dB or less, and isolation between a transmitted signal and a received signal can be improved in a wide frequency range from 0 GHz to 10 GHz, as compared with an optical transceiver module including a single-ended amplifier and a single-ended attenuator.

### Operation Flow

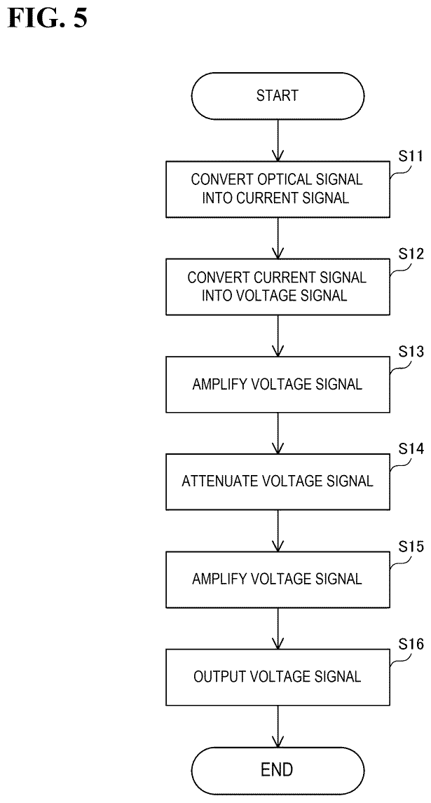

FIG. 5 is a flowchart defining an example of an operation procedure for performing a method of signal amplification using the optical transceiver module according to the embodiment of the present disclosure.

With reference to FIG. 5, first, the received optical signal is converted into a current signal using the PD 11 (step S11).

Next, the current signal obtained through conversion is converted into a voltage signal using the resistor R1 (step S12).

Next, the voltage signal obtained through conversion is amplified by a predetermined amplification factor using the differential amplifier 51 (step S13).

Next, the voltage signal is attenuated by a predetermined attenuation factor using the differential ATT 52 (step S14).

Next, the voltage signal is amplified by a predetermined amplification factor using the differential LNA 53 (step S15).

Next, the amplified electrical signal is output from the output connectors 55A and 55B (step S16).

In the circuit board 50 in the optical transceiver module 101 according to the embodiment of the present disclosure, the first end of the inductor L1 is connected to the ground node Ne, and the first end of the inductor L2 is connected to the connection node Nn to which the negative power supply 54 is connected, but this configuration should not be construed as limiting. The circuit board 50 may be configured such that the first end of the inductor L1 is connected to a connection node to which a positive power supply is connected and the first end of the inductor L2 is connected to the ground node Ne.

In the circuit board 50 in the optical transceiver module 101 according to the embodiment of the present disclosure, the inductance value IV1 of the inductor L1 and the inductance value IV1 of the inductor L2 are set to values for which frequency components of the frequency f1 or higher are blocked, but this configuration should not be construed as limiting. In the circuit board 50, the inductance values IV1 and IV2 may be set to values for which frequency components of the frequency f1 or higher are allowed to pass to a certain extent, depending on the specifications required for the optical transceiver module 101.

In the circuit board 50 in the optical transceiver module 101 according to the embodiment of the present disclosure, the capacitance value CV1 of the capacitor C1 and the capacitance value CV2 of the capacitor C2 are set to values for which frequency components of the frequency f1 or higher are allowed to pass, but this configuration should not be construed as limiting. In the circuit board 50, the capacitance values CV1 and CV2 may be set to values for which frequency components of the frequency f1 or higher are blocked to a certain extent, depending on the specifications required for the optical transceiver module 101.

The optical transceiver module 101 according to the embodiment of the present disclosure includes the termination circuit 60, but this configuration should not be construed as limiting. The optical transceiver module 101 may be configured without the termination circuit 60.

In the optical transceiver module 101 according to the embodiment of the present disclosure, the termination circuit 60 includes the resistor Ra, the capacitor Ca, and the resistor Rb connected in series in this order, but this configuration should not be construed as limiting. For example, the termination circuit 60 may be configured without the resistor Rb. In such a case, the resistance value of the resistor Ra is, for example, 100 Ω. Also, for example, the termination circuit 60 may be configured without the resistor Ra. In such a case, the resistance value of the resistor Rb is, for example, 100 Ω.

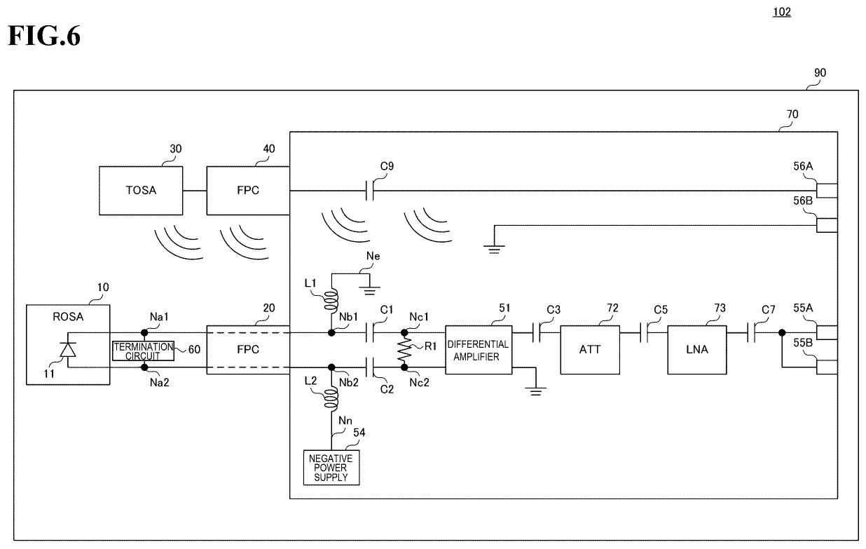

FIG. 6 is a diagram illustrating a circuit configuration of an optical transceiver module according to a modification of the embodiment of the present disclosure. With reference to FIG. 6, an optical transceiver module 102 includes a circuit board 70 instead of the circuit board 50, as compared with the optical transceiver module 101. At least one of the slave station apparatus 111 and the master station apparatus 211 may include the optical transceiver module 102 instead of the optical transceiver module 101.

The circuit board 70 includes an ATT 72 instead of the differential ATT 52, an LNA 73 instead of the differential LNA 53 and does not include the capacitors C4, C6, and C8, as compared with the circuit board 50. The ATT 72 is a single-ended attenuator. The LNA 73 is a single-ended amplifier.

The differential amplifier 51 has the first input terminal connected to the node Nc1, the second input terminal connected to the node Nc2, the first output terminal connected to the first end of the capacitor C3, and the second output terminal connected to a ground node.

The ATT 72 has a first input terminal connected to the second end of the capacitor C3 and a first output terminal connected to the first end of the capacitor C5.

The LNA 73 has a first input terminal connected to the second end of the capacitor C5 and a first output terminal connected to the first end of the capacitor C7.

The capacitor C7 has the first end connected to the first output terminal of the LNA 73 and the second end connected to the output connectors 55A and 55B.

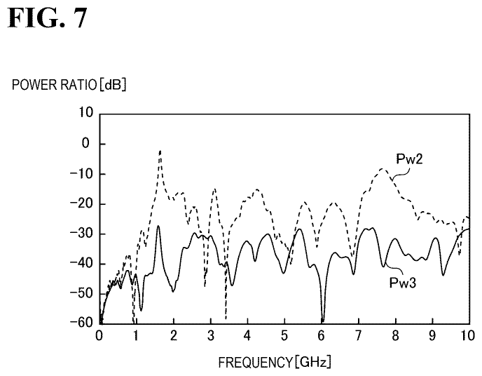

FIG. 7 is a graph illustrating isolation performance of an optical transceiver module according to the modification of the embodiment of the present disclosure. FIG. 7 should be viewed in the same way as FIG. 4. The solid line in FIG. 7 indicates a power ratio Pw3, which is the power ratio Pw obtained by dividing the power of the signal output from the output connectors 55A and 55B by the power of the signal that is input to the input connectors 56A and 56B from outside the optical transceiver module 102 while the optical transceiver module 102, which is an SFP, is not receiving an optical signal.

With reference to FIG. 7, for the optical transceiver module 102, which is an SFP, the power ratio Pw can be reduced to approximately −30 dB or less, and isolation between a transmitted signal and a received signal can be improved in a wide frequency range from 0 GHz to 10 GHz, similarly to the optical transceiver module 101, as compared with an optical transceiver module including a single-ended amplifier and a single-ended attenuator.

Improving isolation between a transmitted signal and a received signal is desirable for an optical transceiver module configured to transmit and receive optical signals.

The signal power level detection circuit described in PTL 1 only receives optical signals, and if a TOSA is further implemented, a transmitted signal and a received signal may interfere with each other, generating noise.

The signal power level detection circuit described in PTL 1 includes a transimpedance amplifier (TIA) as an amplifier. However, it is not easy to obtain a TIA having a dynamic range wide enough to be applied to a system such as an analog RoF system in which an RF signal for wireless communication is transmitted.

The signal power level detection circuit described in PTL 1 has a configuration in which a capacitor with a capacitance value of 470 pF and an inductor with an inductance value of 880 nH are implemented in an optical module. Capacitors and inductors having such electrical characteristics have large component sizes and are not easy to implement in a small ROSA. Specifically, for example, a 470-pF capacitor has one side about 0.5 mm in length, and it is not easy to implement a plurality of such capacitors in a small ROSA formed by a small package with a diameter of 5.6 mm and a receptacle optical connector.

In contrast, in the optical transceiver module 101 according to the embodiment of the present disclosure, the PD 11 converts a received optical signal into a current signal. The resistor R1 converts the current signal obtained through conversion by the PD 11 into a voltage signal. The differential amplifier 51 amplifies the voltage signal obtained through conversion by the resistor R1. The inductor L1 has the first end connected to the ground node Ne and the second end connected to the cathode of the PD 11. The inductor L2 has the first end connected to the connection node Nn and the second end connected to the anode of the PD 11. The capacitor C1 is connected between the node Nb1 located between the cathode of the PD 11 and the inductor L1 and the first end of the resistor R1. The capacitor C2 is connected between the node Nb2 located between the anode of the PD 11 and the inductor L2 and the second end of the resistor R1.

In this manner, using the resistor R1 to convert into a voltage signal a current signal based on a received optical signal enables the voltage signal to be amplified using the differential amplifier 51 having a wide dynamic range. Furthermore, a configuration in which the differential amplifier 51 is used as an amplifier for amplifying a voltage signal enables common-mode noise to be cancelled in a portion susceptible to influence of a transmitted signal, such as a transmission path from the PD 11 to the first-stage amplifier and the first-stage amplifier, in a transmission path from the PD 11 to the output terminal of the optical transceiver module 101. Thus, isolation between a transmitted signal and a received signal can be improved for the optical transceiver module 101, which is configured to transmit and receive optical signals.

The above-described embodiments should be construed as illustrative and not restrictive in all aspects. The scope of the present invention is defined by the claims, rather than the above description, and is intended to include all variations within the scope of the claims and the meaning and the scope of their equivalents.

Each process (each function) in the above-described embodiments is achieved by processing circuitry including one or more processors. The processing circuitry may be composed of an integrated circuit or the like that combines the one or more processors, one or more memories, various analog circuits, and various digital circuits. The one or more memories store a program (instructions) that causes the one or more processors to execute each of the above processes. The one or more processors may execute each of the above processes according to the program loaded from the one or more memories, or may execute each of the above processes according to a logic circuit designed in advance to execute each of the above processes. The one or more processors may be any of various processors suitable for controlling a computer, such as a central processing unit (CPU), a graphics processing unit (GPU), a digital signal processor (DSP), a field programmable gate array (FPGA), and an application specific integrated circuit (ASIC). The plurality of physically separated above processors may cooperate with each other to execute the above processes. For example, the above-described processors installed in each of the plurality of physically separated computers may cooperate with each other via a network, such as a local area network (LAN), a wide area network (WAN), and the Internet, to execute the above processes. The above program may be loaded into the one or more memories from an external server device or the like via the network, or may be stored on a recording medium, such as a compact disc read only memory (CD-ROM), a digital versatile disk read only memory (DVD-ROM), and a semiconductor memory, distributed, and loaded into the one or more memories from the recording medium.

The above description includes features described in the following appendix.

### Appendix 1

An optical transceiver module provided inside a housing having a shielding effect, the optical transceiver module being able to simultaneously transmit and receive an analog optical signal corresponding to a radio signal, the optical transceiver module comprising: a photodetector configured to convert a received analog optical signal into a current signal;
a resistor for converting into a voltage signal the current signal obtained through conversion by the photodetector;
a fully differential amplifier configured to amplify the voltage signal obtained through conversion by the resistor;
a first inductor having a first end and a second end, the first end being connected to a first power supply node, the second end being connected to a cathode of the photodetector;
a second inductor having a first end and a second end, the first end being connected to a second power supply node, the second end being connected to an anode of the photodetector;
a first capacitor connected between a first node and a first end of the resistor, the first node being located between the cathode and the first inductor;
a second capacitor connected between a second node and a second end of the resistor, the second node being located between the anode and the second inductor; and
a fully differentially driven attenuator configured to attenuate the voltage signal amplified by the fully differential amplifier.

### REFERENCE SIGNS LIST

10 ROSA
11 PD (photodetector)
20 FPC (transmission line)
21A, 21B transmission trace
22A, 22B via
30 TOSA
40 FPC
50, 70 circuit board
51 differential amplifier (fully differential amplifier)
52 differential ATT
53 differential LNA
54 negative power supply
55A, 55B output connector
56A, 56B input connector
60 termination circuit
72 ATT
73 LNA
90 housing
101, 101A, 101B, 102 optical transceiver module
111 slave station apparatus
121 RF transceiver unit
191 optical fiber
211 master station apparatus
221 signal processing unit
301 optical communication system
L1, L2 inductor
C1, C2, C3, C4, C5, C6, C7,C8, C9, Ca capacitor
R1, Ra, Rb resistor
Na1, Na2, Nb1, Nb2, Nc1, Nc2 node
Ne ground node (first power supply node)
Nn connection node (second power supply node)
Pw1, Pw2, Pw3 power ratio

1. An optical transceiver module provided inside a housing having a shielding effect, the optical transceiver module being able to simultaneously transmit and receive an analog optical signal corresponding to a radio signal, the optical transceiver module comprising:
a photodetector configured to convert a received analog optical signal into a current signal;
a resistor for converting into a voltage signal the current signal obtained through conversion by the photodetector;
a fully differential amplifier configured to amplify the voltage signal obtained through conversion by the resistor;
a first inductor having a first end and a second end, the first end being connected to a first power supply node, the second end being connected to a cathode of the photodetector;
a second inductor having a first end and a second end, the first end being connected to a second power supply node, the second end being connected to an anode of the photodetector;
a first capacitor connected between a first node and a first end of the resistor, the first node being located between the cathode and the first inductor; and
a second capacitor connected between a second node and a second end of the resistor, the second node being located between the anode and the second inductor.

2. The optical transceiver module according to claim 1, wherein a capacitance value of the first capacitor and a capacitance value of the second capacitor are set to values for which a frequency component included in the current signal is allowed to pass, the frequency component having a frequency of a predetermined value or higher, and
an inductance value of the first inductor and an inductance value of the second inductor are set to values for which the frequency component is blocked.

3. The optical transceiver module according to claim 1, further comprising:
a transmission line connecting an optical receiver including the photodetector and a circuit board on which the first capacitor and the second capacitor are mounted; and
a termination circuit having a first end and a second end, the first end being connected to a third node between the cathode and the transmission line, the second end being connected to a fourth node between the anode and the transmission line, the termination circuit being configured to eliminate a mismatch between a characteristic impedance of the optical receiver and a characteristic impedance of the resistor and the transmission line.

4. The optical transceiver module according to claim 3, wherein the termination circuit includes a first resistor, a capacitor, and a second resistor connected in series in this order.

5. An optical communication system comprising:
a master station apparatus including the optical transceiver module according to claim 1 and a signal processing circuitry; and
a slave station apparatus including the optical transceiver module according to claim 1 and a radio frequency transceiver unit, circuitry.
wherein the master station apparatus is configured to receive an analog signal from a base station apparatus and transmit to the slave station apparatus via an optical fiber the analog optical signal of a first type corresponding to the radio signal of a first type based on the analog signal,
the slave station apparatus is configured to transmit to an antenna the radio signal of the first type corresponding to the analog optical signal of the first type,
the slave station apparatus is configured to receive the radio signal of a second type from the antenna and transmit to the master station apparatus via the optical fiber the analog optical signal of a second type corresponding to the radio signal of the second type, and
the master station apparatus is configured to transmit to the base station apparatus a signal based on the radio signal of the second type corresponding to the analog optical signal of the second type.

6. A method of signal amplification for an optical transceiver module configured to transmit an optical signal corresponding to an analog electrical signal being input and output an analog electrical signal corresponding to an optical signal being received, the method comprising:
converting using a photodetector an optical signal being received into a current signal;
converting using a resistor into a voltage signal the current signal obtained through conversion; and
amplifying using a fully differential amplifier the voltage signal obtained through conversion.

7. The optical transceiver module according to claim 2, further comprising:
a transmission line connecting an optical receiver including the photodetector and a circuit board on which the first capacitor and the second capacitor are mounted; and
a termination circuit having a first end and a second end, the first end being connected to a third node between the cathode and the transmission line, the second end being connected to a fourth node between the anode and the transmission line, the termination circuit being configured to eliminate a mismatch between a characteristic impedance of the optical receiver and a characteristic impedance of the resistor and the transmission line.

8. The optical transceiver module according to claim 7, wherein the termination circuit includes a first resistor, a capacitor, and a second resistor connected in series in this order.
